(19) United States
(12) Patent Application Publication
(10) Pub. No.: US 2002/0123225 A1
(43) Pub. Date: Sep. 5, 2002

(54) Control of Vmin transient voltage drift by using a PECVD silicon oxynitride film at the protective overcoat level

(76) Inventors: Steven P. Zuhoski, Rowlett, TX (US); Mercer L. Brugler, Flower Mound, TX (US); Cameron Gross, Allen, TX (US); Edward L. Mickler, Austin, TX (US)

Correspondence Address: TEXAS INSTRUMENTS INCORPORATED, P O BOX 655474, M/S 3999, DALLAS, TX, 75265

(21) Appl. No.: 10/061,560

(22) Filed: Feb. 1, 2002

Related U.S. Application Data
(60) Provisional application No. 60/265,792, filed on Feb. 1, 2001.

(51) Int. Cl. H01L 21/302; H01L 21/461; H01L 21/311

(52) U.S. Cl. 438/689

(57) ABSTRACT

A method for fabricating a non-FLASH integrated circuit that minimizes Vmin shift. A protective overcoat (134) is deposited to protect and encapsulate the top metal interconnect layer (118). The protective overcoat (134) comprises silicon oxynitride. The protective overcoat (134) is patterned and etched to form bondpad windows either before or after depositing the final metal interconnect layer (136).

### FIELD OF THE INVENTION

The invention is generally related to the field of forming semiconductor devices and more specifically to forming the protective overcoat on semiconductor devices.

### BACKGROUND OF THE INVENTION

In fabricating an integrated circuit, bondpads are formed in the final metal interconnect layer. This can be accomplished with at least two different methods. In the first method, the final metal interconnect layer is deposited. After which, a protective overcoat is formed. Bondpad windows are then patterned and etched into the protective overcoat. In the second method, the protective overcoat is first formed. The bondpad windows are patterned and etched into the protective overcoat. The final metal layer interconnect is then deposited to fill the bondpad windows. A final pattern and etch is accomplished to remove the remaining excess metal. Traditionally, silicon-nitride is used in the protective overcoat with an underlying oxide layer. Silicon-nitride is deposited using SiH₄ and NH₃. Common to these methods of depositing and forming the final metal layer interconnect and protective overcoat is a sinter performed at 435° C. in H₂/N₂ for 30 minutes. This sinter is always performed after the completion of the steps described above.

There are many types of integrated circuits. There are logic ICs, DRAMs (dynamic random access memories), SRAMs (static random access memories), analog ICs, digital signal processors, mixed signal processors, etc. There are also special integrated circuits referred to as FLASH devices or FLASH memories. FLASH devices are UV (ultra-violet light) programmable. FLASH devices require a protective overcoat that is UV transmissive. For this reason, silicon-oxynitride may be used as a protective overcoat for FLASH devices.

### BRIEF DESCRIPTION OF THE DRAWINGS

In the drawings:

FIG. 1 is a cross-sectional diagram of an integrated circuit having a protective overcoat formed according to the invention;

FIG. 2 is a graph of Vmin shift versus film type;

FIG. 3 is a graph of Vmin shift for a pre-sinter and post-sinter condition;

FIG. 4 is a graph of Vmin shift for four conditions: SiON, SiON without sinter, SiN, and SiN without sinter;

FIG. 5 shows the effects of a SiN with N₂ sinter and SiN with a 350° C. sinter compared to a SiON; and

FIG. 6 shows the Vmin shift for SiN with various temperature sinters compared to SiON.

### DETAILED DESCRIPTION OF THE EMBODIMENTS

After fabrication of many integrated circuits, qualification testing is performed. One qualification test is a high voltage/high temperature operating test or (HTOL, burn-in). During burn-in testing of a particular 1.5 V device, a drift in the Vmin was discovered. Vmin is the minimum voltage (with maximum frequency) at which the addressed circuit functions correctly. The Vmin shift was observed to be in excess of 100 mV.

After further evaluation of the device, the cause of the Vmin shift was isolated to the protective overcoat deposition/etch process loop. The inventors believe the Vmin shift to be caused by the outdiffusion of hydrogen from the protective overcoat film by thermal activation. The outdiffusion of hydrogen is believed to degrade the gate oxide thus causing the Vmin shift. Since silicon-nitride was used in the protective overcoat, hydrogen is available through the use of process gases SiH₄ and NH₃ used to form the silicon-nitride. The post deposition hydrogen sinter provides the thermal activation.

The embodiments of the invention reduce the outdiffusion of hydrogen from the protective overcoat at elevated temperatures. The first embodiment replaces the PECVD silicon nitride with PECVD silicon oxynitride having a refractive index less than 1.7 (measured at 673 nm). The second embodiment removes the post PO deposition hydrogen sinter and the third embodiment limits the thermal budget to less than or equal to 350° C. for all post PO deposition processes.

The embodiments of the invention will now be described in conjunction with a non-UV programmable (i.e., non-FLASH) integrated circuit. It will be apparent to those of ordinary skill in the art that the invention may be applied to other non-UV programmable integrated circuits than that shown.

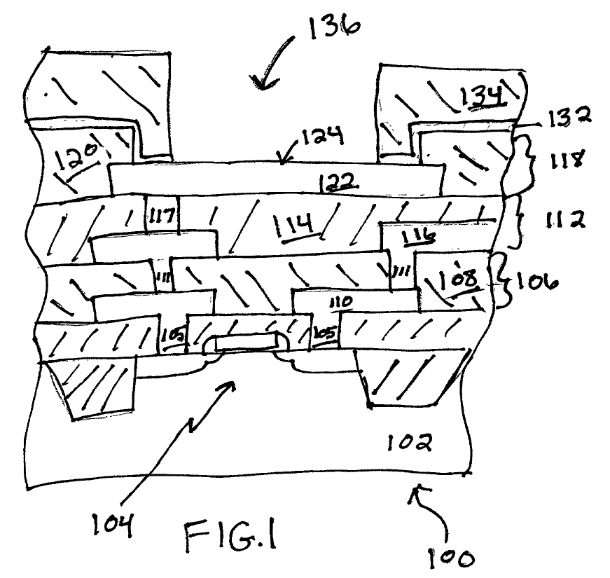

A portion of a semiconductor device 100 formed according to the first embodiment of the invention is shown in FIG. 1. Integrated circuit 100 comprises a semiconductor substrate 102. Semiconductor substrate 102 typically comprises silicon although other semiconductors may alternatively be used. Substrate 102 may or may not also include epitaxial layer formed thereon. Transistors 104 are formed at the surface of substrate 102. Metal interconnect levels 106, 112, 118 are formed over the surface of the substrate. While three interconnect levels are shown, the number of interconnect levels varies depending on the application. Typically, between 2 and 6 levels of metal are used. Each metal interconnect level comprises a dielectric (108, 114, and 120) and a metal (110, 116, 122). The metal is typically either predominantly aluminum or copper and includes barrier layers such as refractory metals and/or their nitrides. Contacts 105 make electrical connection between the first metal 110 and the transistors 104. Vias 111 and 117 make electrical connection between the metal interconnect levels.

The top metal interconnect level (shown here as 118) comprises larger areas of metal referred to as bondpads 124. Bondpads 124 are used to make connection to the semiconductor device 100 during, for example, packaging.

An etchstop layer of silicon nitride may be deposited over the top metal interconnect level if desired. Silicon nitride is useful where copper is used for the metal interconnects in order to encapsulate the copper and prevent diffusion of the copper into the overlying dielectrics.

A protective overcoat is formed over the top metal interconnect layer 118 (and silicon nitride if present). Several layers may in fact form the protective overcoat. The additional layers are useful in accomplishing laser repair. To accomplish laser repair, at least a portion of the bondpads 124 are exposed. The functionality of the device is tested and any needed redundant circuits are identified. The first protective overcoat layer 132 is optionally deposited. Its function is to protect bondpads 124 while fuses are blown using a laser to activate redundant circuitry as needed. First protective overcoat layer 132 comprises an oxide. For example, a PECVD (plasma-enhanced chemical vapor deposition) silicon-dioxide may be deposited. The thickness of first protective overcoat layer 132 may be on the order of 3000 Å. After the desired fuses are blown, a slag etch/clean is performed to remove unwanted material resulting from the laser repair process.

The second/main protective overcoat layer 134 comprises silicon-oxynitride. The thickness of the second protective overcoat layer 134 may be on the order of 8000 Å. PECVD may be used to deposit second protective overcoat layer 134.

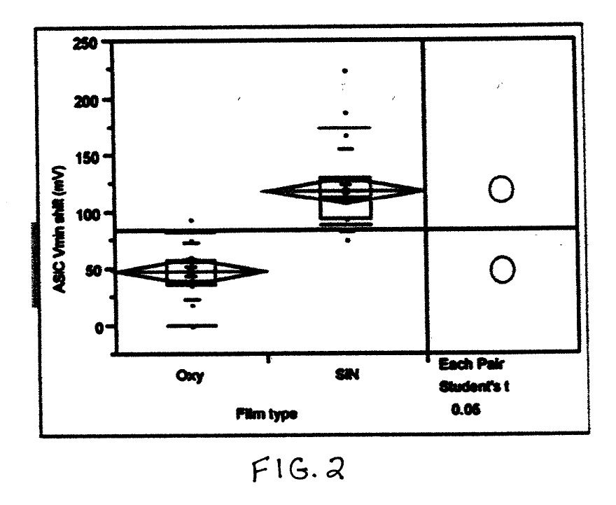

The protective overcoat layers 134 and 132 are patterned and etched to open bondpad windows 136. If desired, instead of forming the top metal interconnect prior to depositing the protective overcoat layers, the top metal interconnect may be formed after the bondpad windows 136 are opened. In that case, after opening the bondpad windows, metal (along with any desired barriers) is deposited. Excess metal material is then removed. Finally, a sinter is performed. FIG. 2 is a graph of Vmin shift versus film type. The graph shows that the mean Vmin shift for silicon oxynitride (refractive index=1.69) is approximately 48 whereas the mean Vmin shift for silicon nitride is approximately 120. The Vmin shift improves by approximately 60%

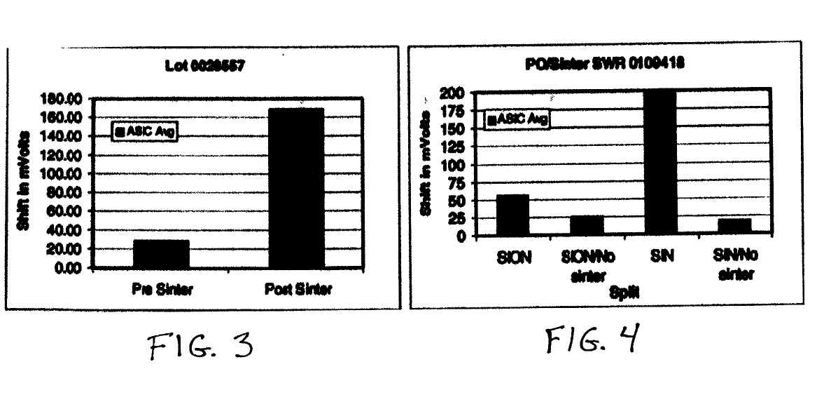

In a second embodiment of the invention, either silicon nitride or silicon oxynitride is used for the second/main protective overcoat layer 134 and the final sinter is removed from the process. FIG. 3 is a graph of Vmin shift for a pre-sinter and post-sinter condition. FIG. 4 is a graph of Vmin shift for four conditions: SiON, SiON without sinter, SiN, and SiN without sinter. Removing the sinter from the SiN case in one lot improved the Vmin shift from in excess of 100 mV to approximately 20 mV. Removing the sinter from the SiON case in one lot-improved the Vmin shift from approximately 55 mV to approximately 25 mV.

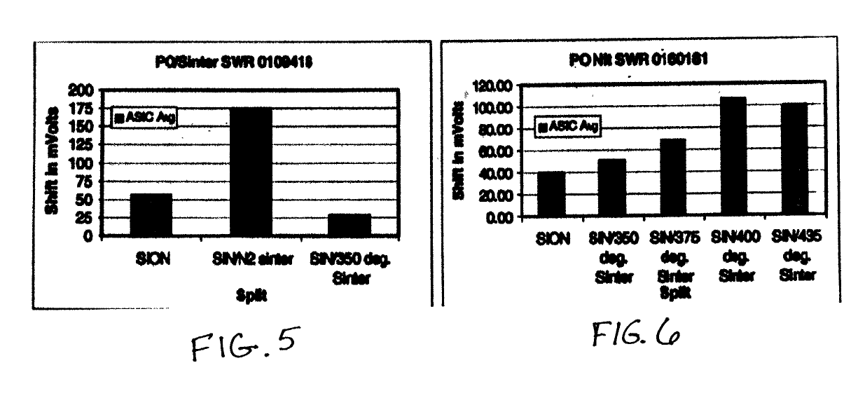

In a third embodiment of the invention, either silicon nitride or silicon oxynitride is used for the second/main protective overcoat layer 134 and the temperature is kept at or below 350° C. for the final sinter and all other post PO deposition processes until packaging of the device. FIG. 5 shows the effects of a SiN with N₂ sinter and SiN with a 350° C. sinter compared to a SiON. The 350° C. sinter reduced the Vmin shift to approximately 30 while still using SiN. FIG. 6 shows the Vmin shift for SiN with various temperature sinters compared to SiON. From these figures, it is apparent that temperature is the overriding contributor to the Vmin shift.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

In the claims:

1. A method for fabricating a non-FLASH integrated circuit, comprising the steps of:
providing a semiconductor body;
forming a top metal interconnect layer over the semiconductor body; and
depositing a protective overcoat over the semiconductor body, wherein said protective overcoat comprises silicon-oxynitride (SiON).

2. The method of claim 1, further comprising the step of:
patterning and etching said protective overcoat to form bondpad windows in said protective overcoat; and
thereafter, performing a sinter.

3. The method of claim 2, wherein said sinter is performed at a temperature less than 350° C.

4. The method of claim 2, further wherein said patterning and etching step is performed after forming said top metal interconnect layer.

5. The method of claim 2, further wherein said patterning and etching step is performed prior to forming said top metal interconnect layer.

6. The method of claim 2, further comprising the step of, after patterning and etching said protective overcoat, packaging the non-FLASH integrated circuit wherein a temperature of the semiconductor body is kept below 350° C. between said patterning and etching step and said packaging step.

7. The method of claim 1, further comprising the step of:
patterning and etching said protective overcoat to form bondpad windows in said protective overcoat; and
thereafter, packaging the non-FLASH integrated circuit wherein no sintering steps are performed between said patterning and etching step and said packaging step.

8. A method for fabricating a non-FLASH integrated circuit, comprising the steps of:
providing a semiconductor body;
forming a top metal interconnect layer over said semiconductor body;
depositing a protective overcoat over said semiconductor body, wherein said protective overcoat comprises silicon-oxynitride (SiON); and
patterning and etching said protective overcoat to form bondpad windows in said protective overcoat.

9. The method of claim 8, wherein said patterning and etching step is performed after said step of forming a top metal interconnect layer.

10. The method of claim 8, wherein said patterning and etching step is performed prior to said step of forming a top metal interconnect layer.

11. The method of claim 8, further comprising the steps of performing a sinter after said patterning and etching step.

12. The method of claim 11, wherein said sinter is performed at a temperature less than 350° C.

13. The method of claim 8, further comprising the step of packaging the non-FLASH integrated circuit wherein a temperature of the semiconductor body is kept below 350° C. between said patterning and etching step and said packaging step.

14. The method of claim 8, further comprising the step of packaging the non-FLASH integrated circuit wherein no sintering steps are performed between said patterning and etching step and said packaging step.

15. A non-flash integrated circuit, comprising:
a top metal interconnect level having bondpads over a semiconductor body; and
a protective overcoat comprising silicon oxynitride accompanying the top metal interconnect level.
